(19) United States
(12) Patent Application Publication
(10) Pub. No.: US 2005/0014373 A1
(43) Pub. Date: Jan. 20, 2005

(54) Method for managing polishing apparatus

(75) Inventors: Koutaro Miyasaka, Toyama (JP); Shinichi Imai, Osaka (JP)

Correspondence Address: Jack Q. Lever, Jr.;McDERMOTT, WILL & EMERY LLP, 600 Thirteenth Street, N.W., Washington, DC, 20005-3096, US

(73) Assignee: Matsushita Electric Industrial Co., Ltd.

(21) Appl. No.: 10/891,097

(22) Filed: Jul. 15, 2004

(30) Foreign Application Priority Data
Jul. 15, 2003 (JP) 2003-197150

(51) Int. Cl. H01L 21/302; H01L 21/461

(52) U.S. Cl. 438/689

(57) ABSTRACT

A method for managing a polishing apparatus including downforce detecting means for detecting a downforce applied to a polishing target wafer, includes steps of: calculating a difference between a first downforce detected by the downforce detecting means at a first period at which the polishing apparatus stands by for polishing the wafer, and a second downforce detected by the downforce detecting means at a second period at which the polishing apparatus polishes the wafer, as an actual downforce actually applied to the wafer at the second period; and monitoring the actual downforce.

### CROSS-REFERENCE TO RELATED APPLICATION

All of the matters disclosed in the specification, the drawings, and the claims of Japanese Patent Application No. 2003-197150 filed on Jul. 15, 2003 are incorporated herein by reference.

### BACKGROUND OF THE INVENTION

The present invention relates to a method for managing a polishing apparatus.

Recently, following high integration of a semiconductor device, importance of planarization technology by polishing a semiconductor element structure with high accuracy has been increasing. In the planarization technology, a chemical mechanical polishing (CMP) technique is an excellent global method which can realize planarization. The CMP technique is used for planarization of an interlayer insulating film, polishing of a surplus oxide film remaining on a semiconductor substrate when an element isolation region is formed, and the like. With the CMP, mechanical polishing and chemical action are combined, thereby polishing a surface of the semiconductor substrate. A polishing state during the CMP largely depends on a mechanical contact state between a polishing cloth and the semiconductor substrate. In order to highly accurately polish an entire surface of the semiconductor substrate, therefore, it is indispensable to control a downforce exerted on the semiconductor substrate during polishing (hereinafter, “polishing downforce”).

A conventional wafer polishing apparatus which controls the polishing downforce will be described with reference to FIGS. 9 and 10.

FIG. 9 is a cross-sectional view which depicts a structure of the conventional wafer polishing apparatus.

The conventional wafer polishing apparatus shown in FIG. 9 includes a rotatable upper surface plate 102 which has a weight of about 700 kg, which is coupled with a bearing member 101, and which is supported by a supporting frame 100, and a lower surface plate 103 which is arranged to face the upper surface plate 102 and which drives rotation. In addition, a load cell 100A, serving as a downforce detecting means for detecting a downforce applied to each wafer 104, which is a polishing target material, is arranged between the supporting frame 100 and the bearing member 101. A liquid filled bath 105 which can contain about 150 kg of pure water is provided on an upper surface of the upper surface plate 102. Liquid supply means for supplying liquid is coupled with the liquid filled bath 105. The liquid supply means includes a plurality of fixed nozzles 106 attached to the supporting frame 100, a plurality of rotary nozzles 107 rotating when the liquid filled bath 105 rotates, and ring-like liquid receivers 108 coupled with the respective rotary nozzles 107 and receiving the liquid dropped from the respective fixed nozzles 106 while rotating.

Further, flow control means composed by, for example, a flow meter 109 and a valve 110, and control means connected to the load cell 100A are arranged in the course of a piping between each fixed nozzle 106 and a liquid supply source, not shown. The liquid supply means is actuated based on a polishing downforce detected by the load cell 100A and applied to the wafer 104, thereby controlling supply of the liquid to the liquid filled bath 105.

As can be seen, the conventional wafer polishing apparatus controls the polishing downforce by controlling an amount of the liquid filled into the liquid filled bath 105 provided on the upper surface of the upper surface plate 102.

FIG. 10 depicts a change in the polishing downforce in the conventional wafer polishing apparatus, relative to time.

As shown in FIG. 10, within one minute from the start of polishing until, about 100 kg of a light downforce (about 20 g/cm²) is applied, the downforce is gradually increased so as to reach a predetermined downforce of, for example, 650 kg (about 120 g/cm²), and the predetermined downforce is held for seven minutes. At this time, the load cell 100A constantly detects the downforce applied to each wafer 104. If it is detected that the detected downforce is lighter than the predetermined downforce, then the flow meter 109 and the valve 110 are controlled to supply the amount of liquid having a weight corresponding to an insufficient amount of the downforce to the liquid filled bath 105 provided on the upper surface of the upper surface plate 102 consecutively (see, for example, Japanese Patent Application Laid-Open No. 09-183059).

Thus, the conventional wafer polishing apparatus is managed by controlling the polishing downforce.

The conventional wafer polishing apparatus controls the polishing downforce using the amount of liquid and, therefore, disadvantageously needs to include the liquid filled bath 105 as a device.

Furthermore, the conventional wafer polishing apparatus controls the polishing downforce using the polishing downforce detected by the load cell 10A. However, a polishing irregularity occurs to each wafer, thereby making it difficult to polish the wafers with high accuracy.

### SUMMARY OF THE INVENTION

The present invention has been achieved in light of the conventional disadvantages. It is an object of the present invention to provide a method for managing a polishing apparatus so that the polishing apparatus can polish a wafer with high accuracy while reducing a polishing irregularity which occurs to each wafer.

In order to solve the conventional disadvantages, the inventors of the present invention carried out various studies. As a result, the inventors discovered that, since the control over the polishing downforce exercised by the conventional wafer polishing apparatus is based only on the downforce during polishing without consideration to the downforce when the apparatus is on standby for polishing, an irregularity of the downforce when the apparatus is on standby for polishing is present and a polishing irregularity thereby occurs to each wafer. The present invention has been achieved in light of the knowledge. According to the present invention, there is provided a method for managing a polishing apparatus comprising downforce detecting means for detecting a downforce applied to a polishing target wafer, the method comprising steps of: calculating a difference between a first downforce detected by the downforce detecting means at a first period at which the polishing apparatus stands by for polishing the wafer, and a second downforce detected by the downforce detecting means at a second period at which the polishing apparatus polishes the wafer, as an actual downforce actually applied to the wafer at the second period; and monitoring the actual downforce.

According to the method for managing the polishing apparatus of the present invention, the actual downforce during polishing which is obtained by subtracting the first downforce during standby for polishing from the second downforce during polishing is measured in light of the irregularity of the downforce during standby for polishing. Therefore, the actual downforce has a high correlation with the polishing rate during polishing (the actual downforce is substantially proportional to the polishing rate during polishing). By monitoring this actual downforce, the polishing apparatus can be managed so as to be able to reduce the polishing irregularity that occurs to each wafer and to perform highly accurate polishing.

In the method for managing the polishing apparatus according to the present invention, it is preferable that the step of monitoring the actual downforce includes a step of calculating a polishing rate for polishing the wafer from the actual downforce, and monitoring the polishing rate thus calculated.

If so, the polishing rate can be calculated from the actual downforce which can be monitored at real time, and the polishing rate can be, therefore, managed at real time. Consequently, the polishing apparatus can be managed so as to be able to reduce the polishing irregularity that occurs to each wafer and to perform highly accurate polishing.

In the method for managing the polishing apparatus according to the present invention, it is preferable that the step of monitoring the actual downforce includes a step of calculating a polishing amount of the wafer from the polishing rate and the second period, and monitoring a residual film value after the wafer is polished, the value being obtained by subtracting the calculated polishing amount of the wafer from a thickness of the wafer before the wafer is polished.

If so, the polishing amount can be calculated using the polishing rate which can be monitored at real time. The polishing amount can be thereby calculated from the polishing rate and the polishing time without measuring the residual film value after polishing, and the residual film value after polishing can be obtained simultaneously with the end of the polishing.

In the method for managing the polishing apparatus according to the present invention, it is preferable that the step of monitoring the actual downforce includes a step of detecting that an abnormality occurs to the polishing apparatus when the actual downforce is out of a desired downforce range.

If so, the polishing rate has a high correlation with the actual downforce. Therefore, by managing the polishing rate using the actual downforce, it is possible to detect occurrence of an abnormality of the polishing apparatus. Consequently, the polishing apparatus can be managed so as to be able to reduce the polishing irregularity that occurs to each wafer and to perform highly accurate polishing. Further, since the polishing rate is managed using the actual downforce which can be monitored at real time, the detection of the abnormality can be performed within a short time. The time required to deal with the occurrence of the abnormality can be greatly reduced.

In the method for managing the polishing apparatus according to the present invention, it is preferable that the step of monitoring the actual downforce includes a step of giving a warning when it is detected that the abnormality occurs.

If so, the polishing apparatus can be managed so as to be able to reduce the polishing irregularity that occurs to each wafer and to perform highly accurate polishing. In addition, the time required to deal with the occurrence of the abnormality can be greatly reduced.

In the method for managing the polishing apparatus according to the present invention, it is preferable that the step of monitoring the actual downforce includes a step of calibrating an origin of a load cell serving as the downforce detecting means when it is detected that the abnormality occurs.

In the method for managing the polishing apparatus according to the present invention, it is preferable that the step of monitoring the actual downforce includes a step of stopping the polishing apparatus when the warning is given.

### BRIEF DESCRIPTION OF THE DRAWINGS

FIG. 1 is a schematic diagram of a polishing apparatus employed to describe a method for managing a polishing apparatus in the first embodiment of the present invention.

FIG. 2 is a flowchart which depicts the method for managing the polishing apparatus in the first embodiment of the present invention.

FIG. 3 is a chart which shows downforces at a period at which the polishing apparatus stands by for polishing a wafer and at a period at which the polishing apparatus polishes the wafer in the first embodiment of the present invention.

FIG. 4A is a chart which depicts a relationship between an average downforce and a polishing rate, and FIG. 4B is a chart which depicts a relationship between an actual downforce and the polishing rate.

FIG. 5 is a chart which depicts the relationship between the actual downforce and the polishing rate.

FIG. 6 is a chart which depicts a relationship between actual downforce history and time obtained by managing a tendency for determining a PM execution timing.

FIGS. 7A and 7B are control circuit diagrams of a polishing apparatus in the second embodiment of the present invention.

FIGS. 8A and 8B are charts which show downforces at a period at which the polishing apparatus stands by for polishing a wafer and at a period at which the polishing apparatus polishes the wafer in the second embodiment of the present invention.

FIG. 9 is a schematic diagram which depicts a conventional polishing apparatus.

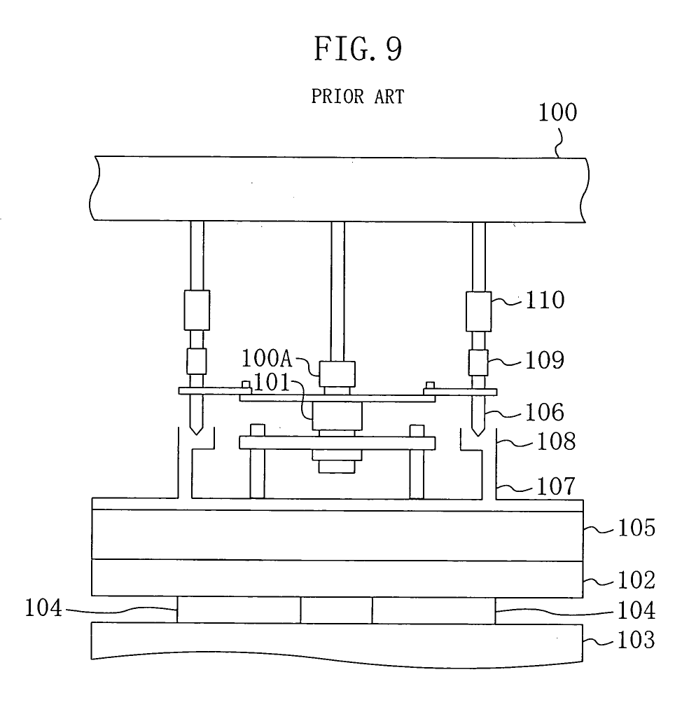

FIG. 10 is a chart which depicts a relationship between a polishing downforce and time during polishing in the conventional polishing apparatus.

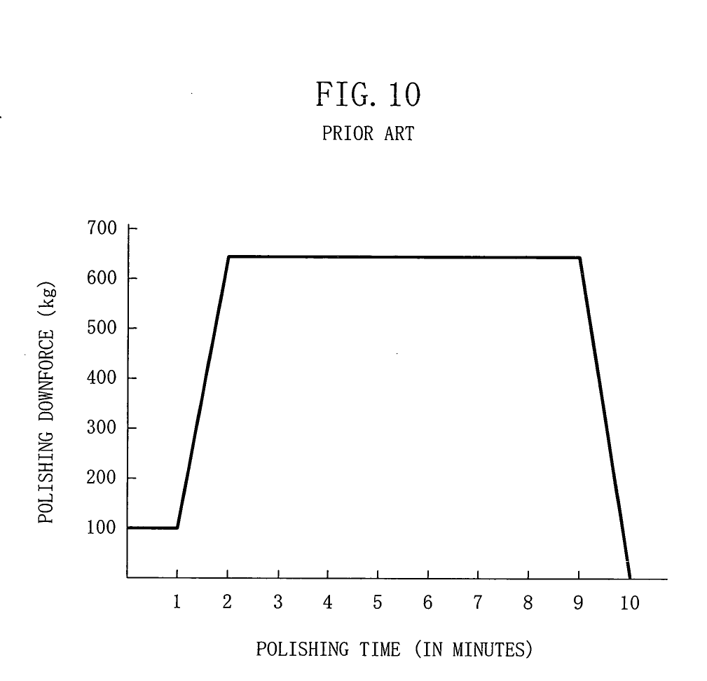

### DETAILED DESCRIPTION OF THE INVENTION

Hereinafter, preferred embodiments of the present invention will be described with reference to the accompanying drawings, in which the same reference numerals denote the same components.

Embodiment 1

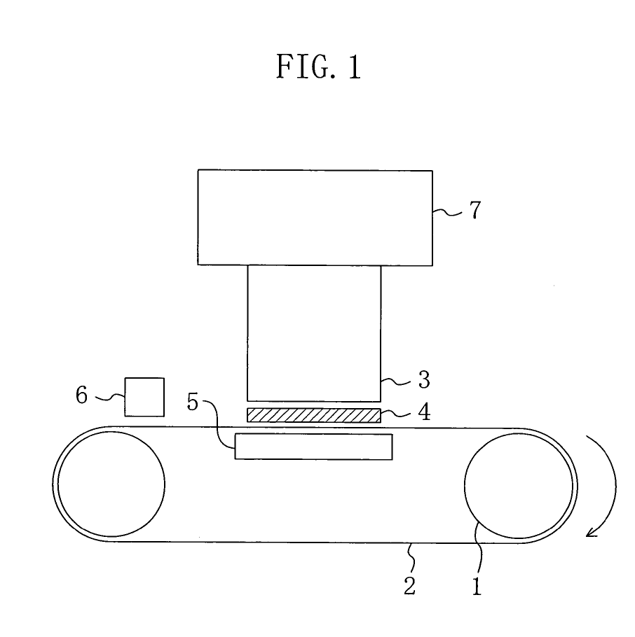

A method for managing a polishing apparatus in the first embodiment of the present invention will be described with reference to FIGS. 1 to 6.

One example of the polishing apparatus employed to describe the method for managing the polishing apparatus in the first embodiment of the present invention will first be described with reference to FIG. 1.

As shown in FIG. 1, a polishing pad 2 is scanned straight by rotation of rollers 1. A semiconductor substrate (wafer) 4 supported by a polishing head 3 and including a polishing target film is held so that a polishing target surface faces the polishing pad 2. A platen 5 is provided opposite to the semiconductor substrate 4 across the polishing pad 2. The polishing apparatus polishes the semiconductor substrate 4 while supplying a slurry, serving as a polishing compound, from a slurry nozzle 6. A load cell (downforce detecting means) 7 detects downforces applied between the polishing head 3 and the platen 5 at a period at which the polishing apparatus stands by for polishing the semiconductor substrate 4 (hereinafter, “first period”) and at a period at which the polishing apparatus polishes the semiconductor substrate 4 (hereinafter, “second period”), respectively. The first period at which the polishing apparatus stands by for the polishing of the semiconductor substrate 4 normally corresponds to a period at which the polishing apparatus is in an idling state, for example, at a period at which the semiconductor substrate 4 as the polishing target is exchanged. The second period normally corresponds to a period at which the polishing apparatus polishes, for example, one semiconductor substrate 4.

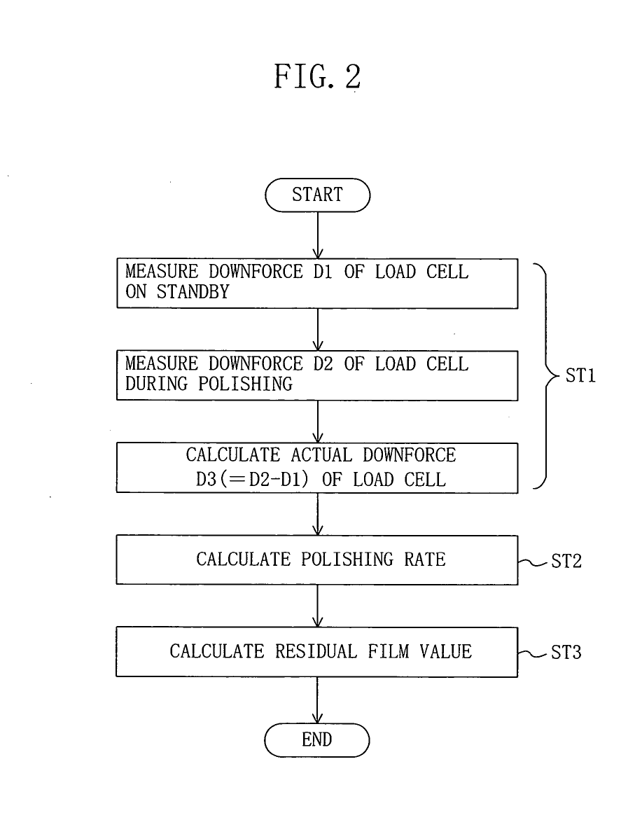

The outline of the method for managing the polishing apparatus in the first embodiment of the present invention will be described with reference to FIG. 2.

As shown in FIG. 2, in a step ST1, the polishing apparatus detects an actual downforce detected by the load cell 7. Specifically, after measuring the downforce detected by the load cell 7 at the first period (hereinafter, the downforce will be referred to as “first downforce”), the polishing apparatus measures the downforce detected by the load cell 7 at the second period (hereinafter, the downforce will be referred to as “second downforce”). The polishing apparatus calculates a difference between the measured first downforce and the measured second downforce as the actual downforce actually applied to the semiconductor substrate 4 at the second period.

In a step ST2, the polishing apparatus calculates a polishing rate. Namely, the polishing apparatus calculates the polishing rate from the actual downforce calculated in the step ST1.

In a step ST3, the polishing apparatus calculates a residual film value. Namely, the polishing apparatus calculates a residual film value of the polishing target film of the semiconductor substrate 4 using a polishing time and the polishing rate calculated in the step ST2.

In this way, with the method for managing the polishing apparatus in the first embodiment, the actual downforce, the polishing rate, and the residual film value are calculated and the calculated values are monitored, whereby the polishing apparatus can be managed so as to be able to prevent a polishing irregularity of each semiconductor substrate 4 and to polish the semiconductor substrate 4 with high accuracy, as will be described later.

The steps ST1 to ST3 shown in FIG. 2 will next be described in detail.

<Step ST1 (Measurement of Actual Load)>

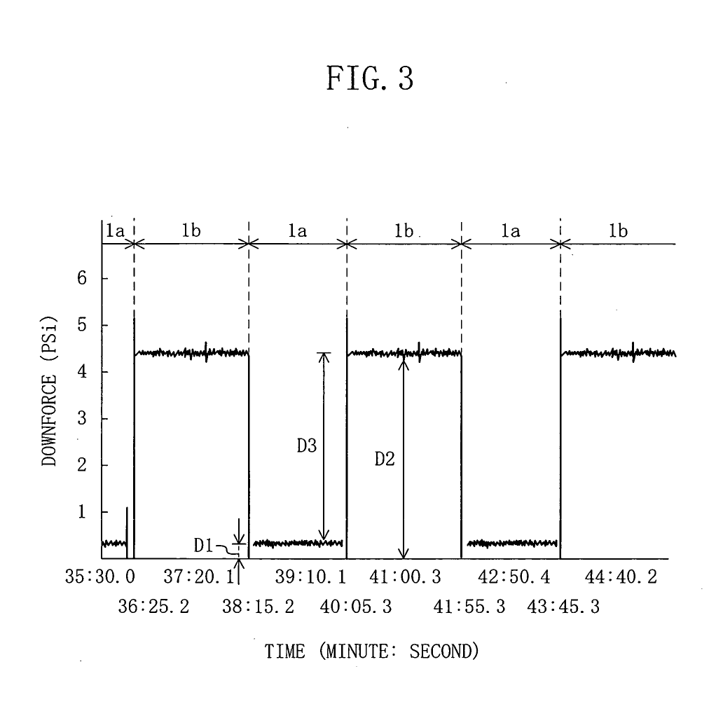

As shown in FIG. 3, at a first period 1a at which the polishing apparatus stands by for polishing the semiconductor substrate 4, the first downforce is applied. Specifically, in the example of FIG. 3, at the first period 1a, an average D1 of the first downforce is applied. At a second period 1b at which the polishing apparatus polishes the semiconductor substrate 4, the second downforce is applied. Specifically, in the example of FIG. 3, at the second period 1b, an average D2 of the second downforce is applied.

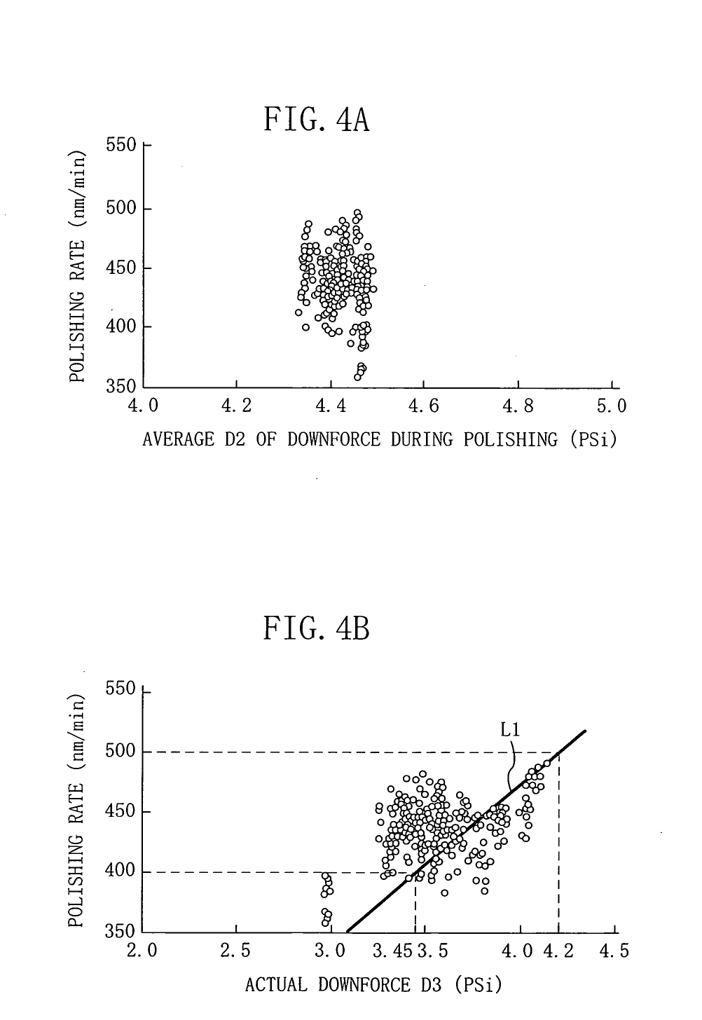

The relationship between the second downforce and the polishing rate at the second period 1b at which the polishing apparatus polishes the semiconductor substrate 4 will be described with reference to FIG. 4A. In FIG. 4A, a horizontal axis indicates the average D2 of the second downforce at the second period 1b, and a vertical axis indicates the polishing rate at the second period 1b.

As is obvious from FIG. 4A, if the average D2 of the second downforce at the second period 1b is in a range of 4.3 to 4.5 (PSi), the polishing rate is distributed in a range of 350 to 500 (nm/min). Namely, an irregularity of the average D2 of the second downforce is 3a and a magnitude of the irregularity is as small as about 0.11 (PSi). However, the polishing rate greatly fluctuates mainly between 450+50 (mm/min). Thus, the polishing rate does not depend on the average D2 of the second downforce.

In the first embodiment of the present invention, therefore, the polishing apparatus measures the first downforce (specifically, the average D1 of the first downforce) at the first period 1a and then measures the second downforce (specifically, the average D2 of the second downforce) at the second period 1b. Thereafter, the polishing apparatus calculates the difference (D2-D1) between the first downforce (specifically, the average D1 of the first downforce) and the second downforce (specifically, the average D2 of the second downforce) thus measured, as an actual downforce D3 actually applied to the semiconductor substrate 4 at the second period 1b.

The relationship between the actual downforce D3 and the polishing rate at the second period 1b will be described with reference to FIG. 4B. In FIG. 4B, a horizontal axis indicates the actual downforce D3 and a vertical axis indicates the polishing rate at the second period 1b.

As is obvious from FIG. 4B, the polishing rate is substantially proportional to the actual downforce D3 as indicated by a line L1. This shows that, if the actual downforce D3 actually applied to the semiconductor substrate 4 is monitored, the polishing rate at the second period 1b can be monitored as will be described later. As a result, the polishing apparatus can be managed so as to be able to prevent the polishing irregularity of each semiconductor substrate 4 and to polish the semiconductor substrate 4 with high accuracy.

<Step ST2 (Calculation of Polishing Rate)>

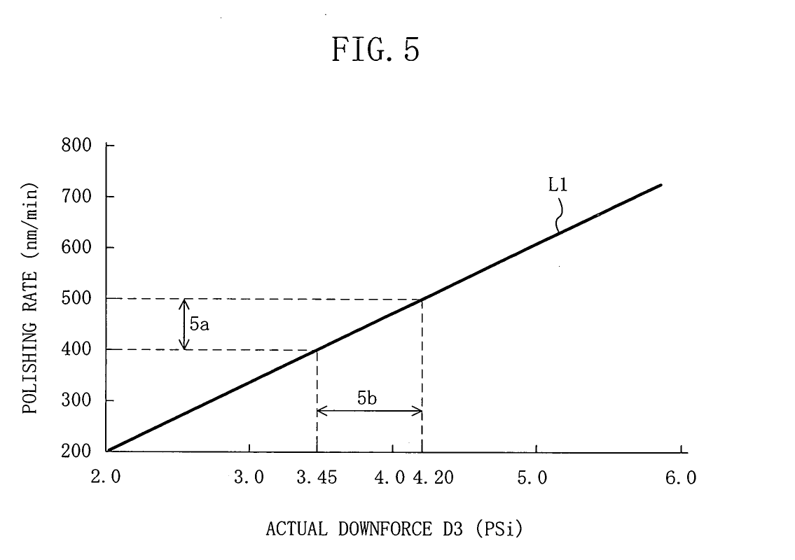

FIG. 5 is a chart on a changed scale from the chart which depicts the relationship between the actual downforce D3 and the polishing rate shown in FIG. 4B. A method for obtaining the polishing rate from the actual downforce D3 will be specifically described.

The polishing apparatus polishes the semiconductor substrate 4 for a fixed period of time and a range 5a of a desired polishing rate is set at 450±50 (nm/min) based on a standard of a polishing amount. In this case, as already described with reference to FIG. 4B, the polishing rate is substantially proportional to the actual downforce D3 as indicated by the line L1. In light of this relationship, a standard range 5b of the actual downforce D3 is set at 3.45 to 4.20 (PSi) so as to monitor whether the polishing rate is within the range 5a using the actual downforce D3. By so setting, the polishing rate can be monitored using the actual downforce D1 measured in the step ST1, and the polishing rate can be, therefore, measured at real time. Conventional polishing rate measurement is conducted by measuring a thickness of the polishing target film after polishing and measuring a difference between the measured thickness and a thickness of the polishing target film before polishing. With the method for managing the polishing apparatus according to the present invention, by contrast, the polishing rate can be monitored using the actual downforce D3. Therefore, an abnormality of the polishing rate can be detected during polishing. Accordingly, the polishing apparatus can be managed so as to be able to prevent the polishing irregularity of each semiconductor substrate 4 and to polish the semiconductor substrate 4 with high accuracy.

Further, if the abnormality is thus detected, a warning can be given, for example, by sounding an alarm and the polishing apparatus can be stopped. In addition, with the method of the present invention, the polishing rate is managed using the actual downforce which can be monitored at real time. As a result, the abnormality can be detected in a short period of time and time required to deal with occurrence of the abnormality can be, therefore, greatly reduced.

The dealing when the abnormality occurs will be described.

Specifically, based on a result of monitoring the actual downforce D3 measured in the step ST1, preventive maintenance (“PM”) is performed.

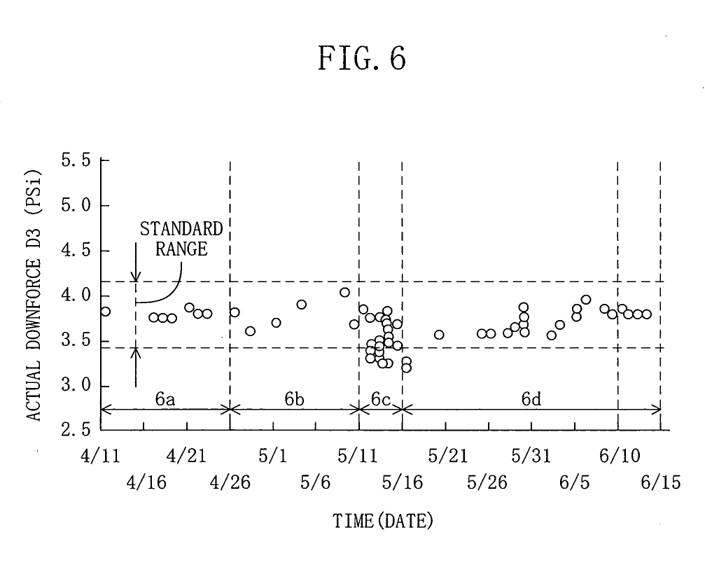

FIG. 6 is a chart which depicts a manner in which a tendency is managed for determining timing of executing the PM. In FIG. 6, a horizontal axis indicates time (date) and a vertical axis indicates the actual downforce D3.

As shown in FIG. 6, periods 6a and 6b correspond to a preset PM cycle. At the periods 6a and 6b, the actual downforce D3 does not deviate from the standard range (3.45 to 4.20 (PSi)). At a period 6c, the actual downforce D3 deviates from the standard range, thereby indicating that the PM should be performed at the period 6c. As the PM, an origin of the load cell 7 is calibrated. At a period 6d, the actual downforce D3 is within the standard range for longer time than the preset PM cycle (periods 6a and 6b). Therefore, at the period 6d, the polishing apparatus can be actuated without performing the PM for longer time than the time for which the PM is performed, after the preset PM cycle. By thus monitoring the actual downforce D3 and managing the tendency, the PM can be performed at optimum timing. Accordingly, the operating rate of the polishing apparatus, and therefore its productivity, can be improved.

In the example of FIG. 6, the tendency is managed with the horizontal axis indicating the date. Alternatively, the tendency may be managed not by the date but by time. Further, if the managing time is set shorter, a failure occurrence rate can be made lower.

<Step ST3 (Calculation of Residual Film Value)

In the step ST3, after calculating the polishing amount of the polishing target film of the semiconductor substrate 4 from the polishing rate measured in the step ST2 and the second period 1b which corresponds to the polishing time, the polishing apparatus subtracts the calculated polishing amount from a thickness of the polishing target film measured before polishing. The thickness of the polishing target film after polishing can be thereby calculated. In this way, in the step ST3, the polishing apparatus can calculate the polishing amount by using the polishing rate which can be monitored at real time in the step ST2. Therefore, the polishing amount can be calculated from the polishing rate and the polishing time without measuring the residual film value after polishing, thereby making it possible to obtain the residual film value after polishing simultaneously with the end of the polishing.

Embodiment 2

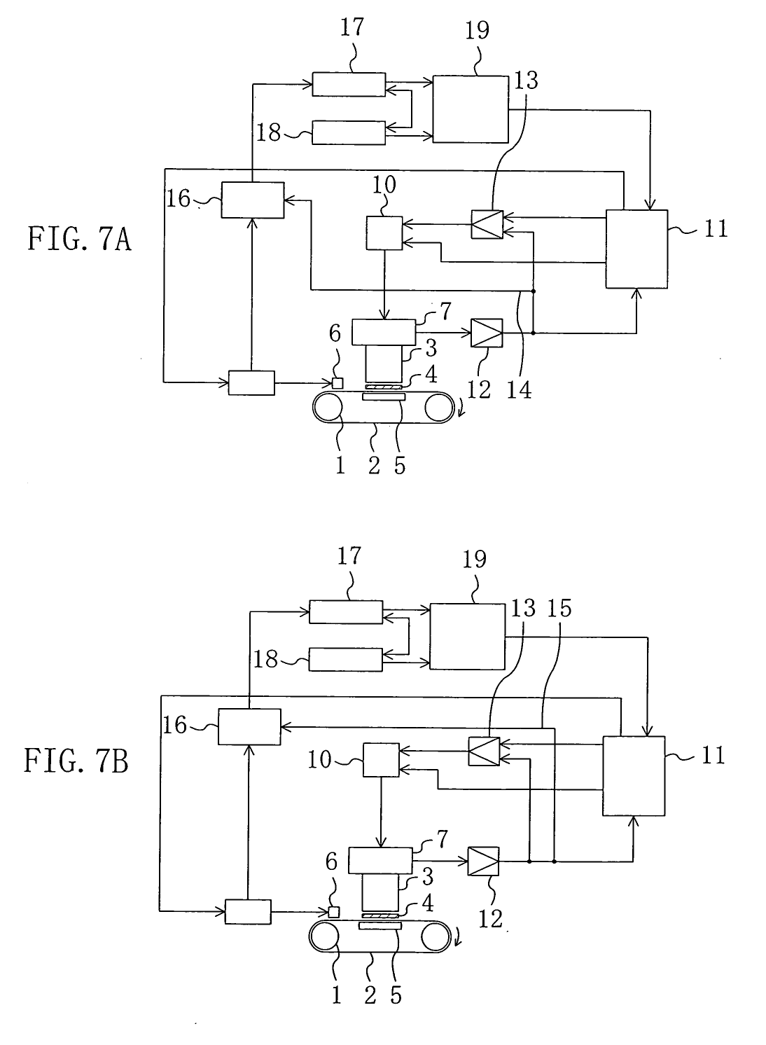

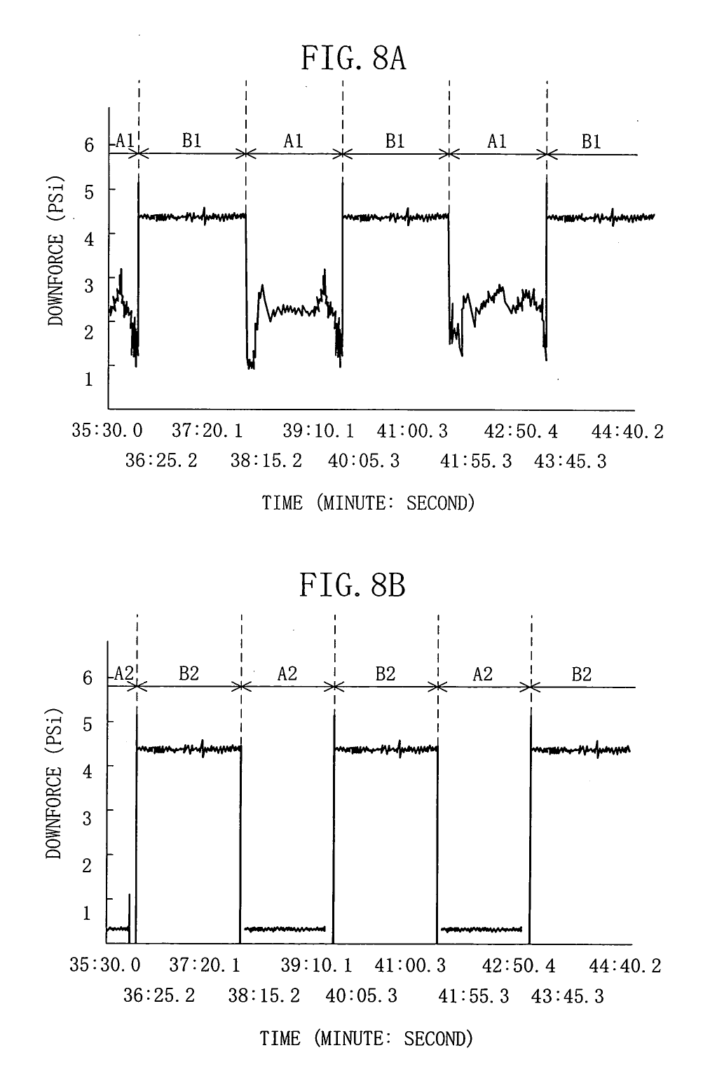

A method for managing a polishing apparatus in the second embodiment of the present invention will be described with reference to FIGS. 7A, 7B, 8A, and 8B.

FIGS. 7A and 7B show a control circuit and a polishing apparatus employed for the method for managing the polishing apparatus in the second embodiment.

The polishing apparatus shown in FIGS. 7A and 7B will first be described.

A polishing pad 2 is scanned straight by rotation of rollers 1. A semiconductor substrate (wafer) 4 supported by a polishing head 3 and including a polishing target film is held so that a polishing target surface faces the polishing pad 2. A platen 5 is provided opposite to the semiconductor substrate 4 across the polishing pad 2. The polishing apparatus polishes the semiconductor substrate 4 while supplying a slurry, serving as a polishing compound, from a slurry nozzle 6. A load cell (downforce detecting means) 7 detects downforces applied between the polishing head 3 and the platen 5 at a period at which the apparatus stands by for polishing the semiconductor substrate 4 (“first period”) and at a period at which the polishing apparatus polishes the semiconductor substrate 4 (“second period”), respectively.

A drive circuit of a servo valve 10 which controls the downforces detected by the load cell 7 will be described.

A voltage signal input from a host computer 11 and indicating a predetermined downforce is compared with a voltage signal input through a first amplifier 12 and indicating the downforce detected by the load cell 7 by a second amplifier 13. A voltage signal indicating a difference between the both voltage signals is input to the servo valve 10. The servo valve 10 controls the downforce so that the difference between the predetermined downforce and the downforce detected by the load cell 7 is zero.

Such a feedback circuit tends to be influenced by noise. Namely, in the circuit shown in FIG. 7A, a control signal line 14 led from the first amplifier 12 is connected to a data logger 16. Therefore, when an abnormality such as the noise occurs, the circuit which monitors the downforce is badly damaged, resulting in occurrence of a trouble to polishing processing. It is, therefore, preferable to constitute the circuit so that a signal line 15 other than the control signal line 14 (see FIG. 7A) led from the first amplifier 12 is provided and so that the signal line 15 is connected to the data logger 16 as shown in FIG. 7B.

The reason that the circuit is preferably constituted as shown in FIG. 7B will be described with reference to FIGS. 8A and 8B.

FIGS. 8A and 8B depict a change in waveforms of downforces, at periods at which the polishing apparatus stands by for polishing the semiconductor substrate 4 (hereinafter, “polishing standby periods A1 and A2”) and at periods at the polishing apparatus polishes the semiconductor substrate 4 (hereinafter, “polishing processing periods B1 and B2”), with the passage of time. Specifically, FIG. 8A is a chart which shows an instance of monitoring the downforce by the circuit which uses the control signal line 14 as shown in FIG. 7A. FIG. 8B is a chart which shows an instance of monitoring the downforce by the circuit which uses the signal line 15 as shown in FIG. 7B.

The downforce shown in FIG. 8A is compared with the downforce shown in FIG. 8B. The downforce at the polishing processing period B1 and the downforce at the polishing processing period B2 are within a range of 4.3 to 4.4 (PSi). Therefore, these downforces are equivalent. The downforce at the polishing standby period A1 is within a range of 1.0 to 3.0 (PSi) whereas the downforce at the polishing standby period A2 is within a range of 0.4 to 0.5 (PSi). Therefore, the downforce at the polishing standby period A1 is twice or more the downforce at the polishing standby period A2. The reason is as follows. Since the circuit employs the control signal line 14 as shown in FIG. 7A, contact failure occurs to a measurement terminal and the circuit is influenced by the noise. That is, the actual downforce obtained by subtracting the downforce at the polishing standby period A1 from the downforce at the polishing processing period B1 shown in FIG. 8A is 30 to 75% of the actual downforce shown in FIG. 8B. Obviously, therefore, if the circuit using the control signal line 14 monitors the downforce, the polishing rate is reduced and a polishing abnormality occurs. Accordingly, if the downforce or the like is to be monitored, the circuit is constituted, as shown in FIG. 7B, so that the signal line 15 other than the control signal line 14 led from the first amplifier 12 is connected to the data logger 16. By so constituting, even if the contact failure occurs during measurement, the downforce can be monitored without adversely influencing the polishing processing.

The feedback circuit shown in FIG. 7B will be described.

The data logger 16 automatically transfers the data input through the signal line 15 and indicating the actual downforce detected by the load cell 7 to a data storage section 17. A data processing section 18 performs a statistical processing related to the actual downforce. A data determination section 19 compares the statistically processed data with the preset data indicating the standard of the actual downforce, thereby determining whether the actual downforce is normal or abnormal, and transfers a determination result to the host computer 11. A function of determining whether the actual downforce is normal or abnormal can be realized by an existing circuit arrangement. If so, however, the host computer 11 integrally performs the determination function, an operation processing, instruction of set values, and the like. As a result, a malfunction of each operation of the apparatus, a malfunction of the instruction of the set values, or an abnormality of the determination may possibly occur, and it is difficult to realize prompt determination. In the second embodiment, therefore, it is determined that it is necessary to provide the data processing section 18, the data storage section 17, and the data determination section 19 dedicated to the determination function, and the circuit constituted as shown in FIG. 7B is provided.

The feedback circuit shown in FIG. 7B will be specifically described with reference to the example shown in FIG. 3. The data determination section 19 compares the preset standard (3.45 to 4.20 (PSi)) of the actual downforce D3 with the actual downforce D3 acquired from the data processing section 18, thereby detecting whether the acquired actual downforce D3 is normal or abnormal. The determination result of the data determination section 19 is transferred to the host computer 11. The determination result is fed back to the load cell 7 so that the determination result reflects in the measurement of the load cell 7.

As described so far, by detecting the actual downforce, which fluctuates with the passage of time, at real time, and feeding back the appropriate actual downforce, the actual downforce can be strictly controlled. Accordingly, the thickness of the polishing target film can be kept constant. Consequently, it is possible to prevent the polishing irregularity and to realize highly accurate polishing.

It is noted that the present invention is suited for the method for managing the polishing apparatus which controls the downforce and which prevents the polishing irregularity.

1. A method for managing a polishing apparatus comprising downforce detecting means for detecting a downforce applied to a polishing target wafer, the method comprising steps of:
calculating a difference between a first downforce detected by said downforce detecting means at a first period at which the polishing apparatus stands by for polishing said wafer, and a second downforce detected by said downforce detecting means at a second period at which the polishing apparatus polishes said wafer, as an actual downforce actually applied to said wafer at said second period; and
monitoring said actual downforce.

2. The method for managing a polishing apparatus of claim 1, wherein
the step of monitoring said actual downforce includes a step of calculating a polishing rate for polishing said wafer from said actual downforce, and monitoring said polishing rate thus calculated.

3. The method for managing a polishing apparatus of claim 2, wherein
the step of monitoring said actual downforce includes a step of calculating a polishing amount of said wafer from said polishing rate and said second period, and monitoring a residual film value after said wafer is polished, the value being obtained by subtracting the calculated polishing amount of said wafer from a thickness of said wafer before said wafer is polished.

4. The method for managing a polishing apparatus of claim 1, wherein
the step of monitoring said actual downforce includes a step of detecting that an abnormality occurs to the polishing apparatus when said actual downforce is out of a desired downforce range.

5. The method for managing a polishing apparatus of claim 4, wherein
the step of monitoring said actual downforce includes a step of giving a warning when it is detected that said abnormality occurs.

6. The method for managing a polishing apparatus of claim 4, wherein
the step of monitoring said actual downforce includes a step of calibrating an origin of a load cell serving as said downforce detecting means when it is detected that said abnormality occurs.

7. The method for managing a polishing apparatus of claim 5, wherein the step of monitoring said actual downforce includes a step of stopping the polishing apparatus when said warning is given.
